(19) United States
(12) Patent Application Publication
(10) Pub. No.: US 2026/0301781 A1
(43) Pub. Date: Oct. 1, 2026

(54) SEMICONDUCTOR DEVICE

(71) Applicant: Nuvoton Technology Corporation, Hsinchu Science Park (TW)

(72) Inventor: Yung-Chi LAN, Taichung City (TW)

(21) Appl. No.: 19/305,196

(22) Filed: Aug. 20, 2025

(30) Foreign Application Priority Data
Mar. 27, 2025 (TW) 114111737

(51) Int. Cl. G11C 5/14

(52) U.S. Cl. CPC G11C 5/148

(57) ABSTRACT

A semiconductor device is provided. The semiconductor device includes a first circuit block configured to operate according to a first clock signal. The first circuit block is configured to include a multi-bit synchronizer and a register controller. The register controller is configured to include a first storage element. The semiconductor device includes a second circuit block configured to include a clock gating cell and a data retention circuit. The data retention circuit is coupled to the multi-bit synchronizer. When power is restored to the data retention circuit after the first power supply region is powered off, the state value of the output signal of the first storage element before power-off is provided to the multi-bit synchronizer.

### CROSS REFERENCE TO RELATED APPLICATIONS

This Application claims priority of Taiwan Patent Application No. 114111737, filed on Mar. 27, 2025, the entirety of which is incorporated by reference herein.

### BACKGROUND OF THE INVENTION

### Field of the Invention

The present invention relates to semiconductor devices, and, in particular, it relates to semiconductor devices with low-power consumption and data restoration functions for multi-bit synchronizers.

### Description of the Related Art

In recent years, semiconductor process technology has been continuously improved, and chip efficiency has increased accordingly. However, advanced processes can introduce serious current leakage problems, resulting in additional power consumption. In order to solve this problem, it is common for semiconductor devices to use a power-saving mode design that suppresses current leakage by powering off part of the circuit area.

However, the power-off region may contain a register that stores configurations, which are typically used to control the operation of the circuit in the powered region. Therefore, traditional designs must retain these configurations in power-off regions to ensure that the system can still function in power-saving mode. Especially in the case of a lower frequency clock in the powered region, the signal from a power-off region needs to be processed by a synchronous circuit to ensure the correctness and stability of the signal.

In order to reduce power consumption, the synchronous circuit is placed in the power-off region. However, this design causes the retained value inside the synchronizer to be lost after the system enters the power-saving mode, and the output of the preset value may interfere with the operation of the circuit or even cause abnormalities after waking up.

In addition, the synchronous circuit has some shortcomings, such as the inability to know the synchronization progress, the increase in power consumption due to the continuous operation of the synchronizer, and the loss of the synchronizer set value after power-off. These issues result in an increased circuit area, increased power consumption, and poor synchronization efficiency.

Therefore, a more efficient and reliable synchronous circuit architecture is urgently needed to solve the shortcomings of the above-mentioned prior arts.

### BRIEF SUMMARY OF THE INVENTION

The semiconductor device of one embodiment of this disclosure includes first and second circuit blocks. The first circuit block is configured to receive power from a first power supply region, and is configured to operate according to a first clock signal. The first circuit block includes a multi-bit synchronizer and a register controller. The register controller includes a first storage element with a count of at least one. The second circuit block is configured to receive power from a second power supply region. The second circuit block includes a clock gating cell and a data retention circuit. The clock gating cell is configured to selectively output a second clock signal according to a gating signal. The data retention circuit is coupled to the multi-bit synchronizer. When the semiconductor device enters a power-saving mode, the first power supply region is powered off, and the second circuit block causes the clock gating cell to output the second clock signal according to a save enable signal. When the semiconductor device leaves the power-saving mode, the power supply in the first power supply region is restored, and the second circuit block controls the clock gating cell to stop outputting the second clock signal when the save enable signal is at a second logic level. When power supply is restored to the data retention circuit after the first power supply region is powered off, the state value of the output signal of the first storage element before power-off is provided to the multi-bit synchronizer.

### BRIEF DESCRIPTION OF THE DRAWINGS

FIG. 1 is a schematic diagram of the system architecture of a semiconductor device with a multi-bit synchronizer with low power consumption and data retention functions according to one of the embodiments in this disclosure;

FIG. 2 shows an operation sequence diagram of the semiconductor device in FIG. 1;

FIG. 3 is a schematic diagram of the scheduler with a register according to one of the embodiments in this disclosure;

FIG. 4A is a schematic diagram of a circuit architecture with a write ignore mechanism, and FIG. 4B is a schematic diagram of a circuit architecture with a bus control mechanism;

FIG. 5 shows a sequence diagram illustrating how the bus control mechanism works;

FIG. 6 illustrates the circuit architecture of a multi-bit synchronizer with a multi-power supply region data retention function;

FIG. 7 shows an operation sequence diagram of the multi-bit synchronous circuit in FIG. 6 when data is synchronized;

FIG. 8 shows the waveform of the multi-bit synchronizer in the multi-bit register synchronization control system with multi-power supply region data retention function when entering and leaving the power-saving mode;

FIG. 9 is a schematic diagram of the multi-bit synchronous circuit architecture with the multi-power supply region data retention function of one of the embodiments in this disclosure;

FIG. 10 is a schematic diagram of a semiconductor device that can be applied to a multi-bit synchronizer circuit architecture in a multi-power supply region system in one of the embodiments in this disclosure;

FIG. 11 shows the waveform diagram of the operation of the multi-power supply region data retention and restore mechanism of a semiconductor device in FIG. 10;

FIG. 12 is a schematic diagram of the clock gating circuit architecture of one of the embodiments in this disclosure; and

FIG. 13 is a schematic diagram of the clock gating circuit architecture of another embodiment in this disclosure.

### DETAILED DESCRIPTION OF THE INVENTION

For a clearer understanding of the above-mentioned objectives, features, and advantages of the present disclosure, preferred embodiments are set forth below, with detailed descriptions provided in conjunction with the accompanying drawings.

The invention provides a semiconductor device with a multi-bit synchronizer with low power consumption and data retention function, which can be used in various electronic products, such as smart phones, tablet computers, wearable devices, Internet of Things (Internet of Things; IoT) devices, etc.

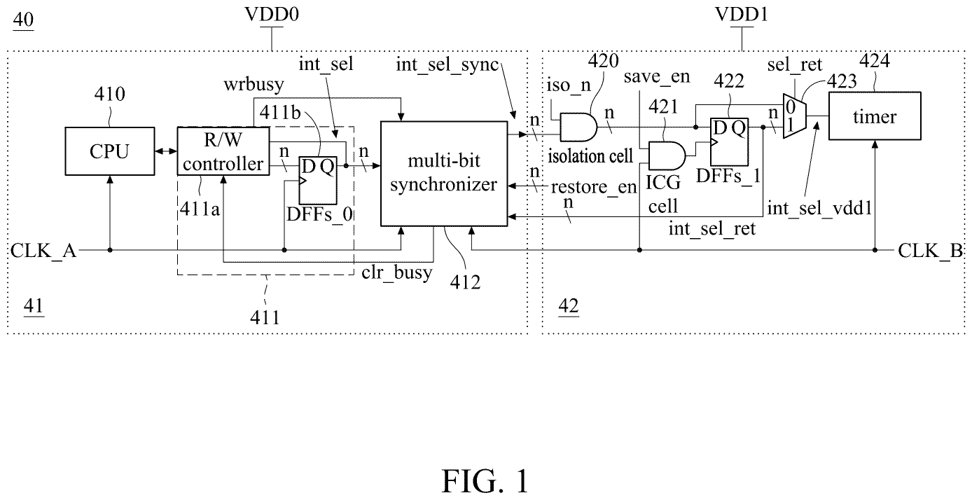

FIG. 1 is a schematic diagram of the system architecture of a semiconductor device with a multi-bit synchronizer with low power consumption and data retention functions according to one of the embodiments in this disclosure.

Referring to FIG. 1, the semiconductor device 40 includes a first circuit block 41 and a second circuit block 42. The first circuit block 41 has a first power supply region, and the second circuit block 42 has a second power supply region. That is, with the power supply division on the semiconductor device 40, at least the first power supply region supplies power to all or part of the first circuit block 41, and the second power supply region supplies power to all or part of the second circuit block 42. In the following, the first power supply region and second power supply region are marked at VDD0 and VDD1, respectively. The first power supply region VDD0 can be powered off when the system enters the power-saving mode, while the second power supply region VDD1 maintains power supply in the power-saving mode.

In one of the embodiments, the first circuit block 41 includes a central processing unit (CPU) 410, a register controller 411, and a multi-bit synchronizer 412. The register controller 411 includes a read/write controller (R/W controller) 411a and a storage element (DFFs_0) 411b. In one of the embodiments, the register controller 411 is composed of a R/W controller 411a and a storage element 411b. The storage element 411b can be various forms of flip-flops or latches; Here, for example, the D-type flip-flop (DFFs_0). The first circuit block 41 operates according to the clock signal CLK_A. The CPU 410 can access the storage element 411b in the register controller 411 through the R/W controller 411a.

In one of the embodiments, the output value of the storage element 411b can be used to control the function of a specific circuit, such as setting the counting interval of a timer 424.

In this diagram, when the system enters power-saving mode, the first power supply region VDD0 will be powered off, leaving only the power supply of the second power supply region VDD1. To ensure that the timer counts properly in power-off mode, the state of the storage element 411b must be retained in order to continue to control the timer in power-off mode. Since the storage element 411b and the register controller 411 are usually written in the same piece of code in Verilog Code, they are defined in the same module. In the back-end circuit layout project, the smallest unit of the specified circuit power supply region is usually in modules, so the entire register controller module, including the storage element 411b, will be classified in the first power supply region VDD0 (i.e., power-off region).

If the timer circuit in the second power supply region VDD1 is controlled by the output value of storage element 411b in power-off mode, the value of storage element 411b must be transferred to the second power supply region VDD1. In this example, at least one storage element 422 (flip-flop DFFs_1) is configured in the second power supply region VDD1 for the purpose of storing the value of the storage element 411b and providing the stored value to the timer as a control signal after storage completion. The “n” shown in the FIG. 1 represents the number of bits of the registers, and its value is based on the actual circuit specifications.

In one of the embodiments, the function of the multi-bit synchronizer 412 is to synchronize an output signal int_sel in the clock domain of a clock signal CLK_A (transmit_clk) to a synchronous output signal int_sel_sync in the clock domain of a clock signal CLK_B (receive_clk). When the write pulse signal wrbusy is logic high (e.g., wrbusy=1), the output signal int_sel has been updated, but is not limited to.

Although the multi-bit synchronizer 412 can synchronize the signal from the clock signal CLK_A to the clock signal CLK_B, it provides opportunities for improvement such as the inability to know the progress of synchronization, and the need for the multi-bit synchronizer 412 to continuously detect the status of the signal, resulting in the clock signal CLK_B at the receiver must continue to operate, resulting in additional waste of power consumption. In addition, when the first power supply region VDD0 of the multi-bit synchronizer 412 is powered off in power-saving mode, the multi-bit synchronizer 412 will lose the previously synchronized value, resulting in a possible operation error after the system wakes up.

In one of the embodiments, the second circuit block 42 includes an isolation cell 420, an integrated clock gating cell 421, a storage element (DFFs_1) 422, a multiplexer 423 and a timer 424.

In one of the embodiments, the isolation cell 420 may be an AND gate; In one of the embodiments, the ICG cell 421 may be an AND gate; In one of the embodiments, the storage element 422 may be a flip-flop (Flip-Flop) or a latch of various forms, wherein, for example, a D-type flip-flop (DFFs_1).

In one of the embodiments, the second circuit block 42 operates according to the second clock signal CLK_B, wherein the frequency of the second clock signal CLK_B may be lower than the frequency of the first clock signal CLK_A.

In one of the embodiments, the multi-bit synchronizer 412 is configured in the first power supply region VDD0 that can be powered off, and the data retention and restore mechanism in the power-saving mode is implemented through the components and control signals in the second circuit block 42. When the semiconductor device 40 enters power-saving mode, the first power supply region VDD0 is powered off, while the second power supply region VDD1 remains powered.

Specifically, if the register controller 411 is configured in the first power supply region VDD0, so when the semiconductor device 40 enters the power-saving mode, because power supply in the first power supply region VDD0 was interrupted, the register controller 411 and the storage element 411b will be powered off, and if the timer 424 in the second circuit block 42 needs to be controlled by the storage element 411b in the power-saving mode, the set value of the storage element 411b must be transferred to the second power supply region VDD1 of the second circuit block 42. In this example, the storage element 422 of the second circuit block 42 is configured in the second power supply region VDD1 for the purpose of storing the set value of the storage element 411b, which is then provided to the timer 424.

In one of the embodiments, the multi-bit synchronizer 412 is configured in the first power supply region VDD0 that can be powered off, and the data retention and restore mechanism in the power-saving mode is implemented through the components and control signals in the second circuit block 42. When the semiconductor device 40 enters power-saving mode, the first power supply region VDD0 is powered off, while the second power supply region VDD1 remains powered.

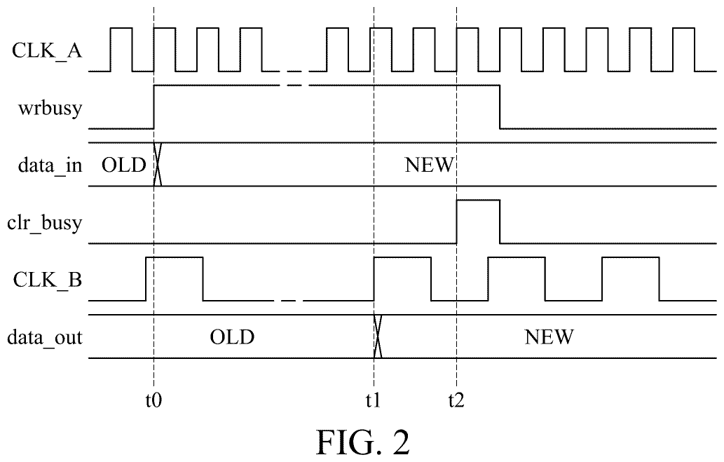

FIG. 2 shows the operation sequence diagram of the semiconductor device in FIG. 1. In one of the embodiments, the semiconductor device 40 may be used as a register control system, but is not limited to.

As shown in FIG. 2, at time t0, while the data signal data_in (or input signal) is updated, the signal wrbusy will be pulled to high level, and the multi-bit synchronizer 412 is driven to start the synchronization task. At time t1, the multi-bit synchronizer 412 completes the synchronization task, and the data signal (or output signal) data_out is updated from the old value (marked as OLD in the FIG. 2) to the new value (marked as NEW in the FIG. 2). Then, at time t2, the clear busy signal clr_busy is transitioned to high level, which is used to clear the write pulse signal wrbusy, and after the write pulse signal wrbusy is cleared to low level, the user is allowed to modify the content of the register again, but is not limited to.

In one of the embodiments, when CPU 410 needs to update the set value of storage element 411b, data is written to storage element 411b through a R/W controller 411a, while the signal wrbusy is transitioned to logic high to instruct the multi-bit synchronizer 412 to start signal synchronization. At this moment, the multi-bit synchronizer 412 synchronizes the output signal int_sel of the storage element 411b to the clock domain of the clock signal CLK_B, and generates the synchronized output signal int_sel_sync.

In one of the embodiments, before entering the power-saving mode, the second circuit block 42 retains the value of the synchronous output signal int_sel_sync (which is the same as the output signal int_sel at this time) through the clock gating cell 421 and the storage element 422. In one of the embodiments, the second circuit block 42 sets a save enable signal save_en to logic high, so that the clock gating cell 421 outputs a second clock signal CLK_B to the clock input terminal of the storage element 422. At the same time, when the isolation cell 420 in isolation signal iso_n is logic high, the synchronous output signal int_sel_sync is allowed to pass through and pass to the data input terminal D of the storage element 422. At this moment, the storage element 422 is triggered by the second clock signal CLK_B, latches the value of the synchronous output signal int_sel_sync to the output terminal Q of storage element 422, and outputs the value of the synchronous output signal int_sel_sync to the multiplexer 423. In one of the embodiments, the selection signal sel_ret controls the output signal int_sel_vdd1 of the multiplexer 423 to the timer 424 to ensure that the timer 424 can still operate according to the previous set value in power-saving mode.

In one of the embodiments, after the first power supply region VDD0 is powered off, the isolation cell 420 receives the isolation signal iso_n is logic low, thereby forcibly converting the signal of its output to logic low, equivalently blocks the signal of the first circuit block 41, and avoids the noise or uncertainty state after the first power supply region VDD0 is powered off to affect the operation of the second circuit block 42.

In one of the embodiments, after the multi-bit synchronizer 412 completes the synchronization task, the multi-bit synchronizer 412 will send a pulse signal, clear busy signal clr_busy, to the R/W controller 411a, which is used to notify the R/W controller 411a that the synchronization process has completed, and the signal wrbusy can be transitioned to logic low.

Compared with prior art, this disclosure automatically detects the synchronization completion status and generates a notification signal through the hardware circuit, eliminating the need for frequent polling by the CPU 410, thereby improving the system performance.

As mentioned above, the composition of the semiconductor device 40 disclosed herein mainly includes a first circuit block 41 and a second circuit block 42, which are located in different power supply regions VDD0 and VDD1, respectively. The first circuit block 41 includes a CPU 410, a register controller 411 (comprising a R/W controller 41la and a storage element 411b), and a multi-bit synchronizer 412. The second circuit block 42 includes an isolation cell 420, an integrated clock gating cell 421, a storage element 422, a multiplexer 423 and a timer 424.

In one of the embodiments, the control method of the semiconductor device disclosed in this embodiment includes the following steps:

1. Data synchronization and retention: when CPU 410 writes to storage element 411b, trigger multi-bit synchronizer 412 for synchronization. After the synchronization is completed, the second circuit block 42 retains the value of the synchronous output signal int_sel_sync (which is the same as the output signal int_sel at this time) to the storage element 422.

2. Enter the power-saving mode: the first power supply region VDD0 is powered off, and the second power supply region VDD1 keeps powered. The isolation cell 420 blocks the signal of the first circuit block 41. The output signal, selection signal sel_ret, of the storage element 422 is transmitted to the timer 424 through the multiplexer 423.

3. Leave the power-saving mode (data restoration): the first power supply region VDD0 restores the power supply. The second circuit block 42 writes back the output of the storage element 422 to the multi-bit synchronizer 412 through the data retention signal int_sel_ret.

The principle of this disclosure is that the components and control signals in the second circuit block 42 are used to save the output value of the multi-bit synchronizer 412 during the first power supply region VDD0 powered off, and the retained value is restored to the multi-bit synchronizer 412 when required.

In one of the embodiments, the frequency of the first clock signal CLK_A can be set to a frequency higher than the frequency of the second clock signal CLK_B to be suitable for high-performance computing applications. The frequency of the second clock signal CLK_B can be set to a frequency lower than the frequency of the first clock signal CLK_A for low power consumption timers or other peripheral circuits operating in power-saving mode.

In one of the embodiments, the isolation cell 420 can be implemented by means of an AND Gate, and the specific size of the isolation cell 420 depends on the process and design requirements.

In one of the embodiments, the integrated clock gating cell 421 can be implemented by means of an AND Gate, the specific size of the integrated clock gating cell 421 depends on the process and design requirements, so as to reduce the glitch of the clock signal.

In one of the embodiments, the storage element 411b and the storage element 422 may be implemented by using a D-type flip-flop, and the specific size of the storage element 411b and the storage element 422 depend on the process and design requirements.

In one of the embodiments, the multi-bit synchronizer 412 can synchronize 8-bit, 16-bit, 32-bit, or data in more bits, and its specific number of bits depends on the process and design requirements.

In one of the embodiments, the second circuit block 42 can be implemented with different components or circuit architectures according to different application requirements. For example, the isolation cell 420, the integrated clock gating cell 421, the storage element 422, and the multiplexer 423 can be implemented by other types of logic gates or switching circuits, but are not limited to.

In one of the embodiments, in addition to the timer 424, the second circuit block 42 may also contain other circuits that need to remain in operation in power-saving mode, such as a real-time clock (RTC) or a power management unit (PMU), etc., but is not limited to.

In one of the embodiments, the semiconductor device 40 can be applied to a variety of different electronic products, such as a smart phone, a tablet computer, a wearable device, the internet of things (IoT) devices, etc.

In this way, by setting the multi-bit synchronizer in the first power supply region that may be powered off, and utilizing the components and control signals in the second circuit block, the data retention and restore mechanism in the power-saving mode is implemented, the power consumption during the circuit operation is effectively reduced, and the stability and reliability of the system in the power-saving mode are ensured.

In one of the embodiments, the write pulse signal wrbusy is transitioned to a first logic level (e.g., logic high) to indicate that a synchronization process is in progress; And when the synchronization process is completed, the write pulse signal wrbusy is transitioned to a second logic level (e.g., logic low).

According to the above embodiments, the write pulse signal wrbusy can allow the user to perform read operation via CPU, and CPU can observe the status of the write pulse signal wrbusy through the polling mechanism to know whether the synchronization process is completed.

Table 1 shows an example of a register bank in a 32-bit system.

TABLE 1

| 31 | 30 | 29 | 28 | 27 | 26 | 25 | 24 |
|---|---|---|---|---|---|---|---|
| WRBUSY | retention | | | | PAR3 | | |
| 23 | 22 | 21 | 20 | 19 | 18 | 17 | 16 |

retention

| | | | | | | | |
|---|---|---|---|---|---|---|---|
| 15 | 14 | 13 | 12 | 11 | 10 | 9 | 8 |

retention

| | | | | | | | |
|---|---|---|---|---|---|---|---|
| 7 | 6 | 5 | 4 | 3 | 2 | 1 | 0 |

| | | |
|---|---|---|
| retention | PAR2 | PAR1 |

In one of the embodiments, the register bank stores three circuit control parameters PAR1, PAR2, and PAR3, wherein the parameters PAR1 and PAR3 are synchronized to the clock domain of the second clock signal CLK_B, while the parameter PAR2 does not need to be synchronized. Therefore, when the processor modifies the value of the parameters PAR1 or PAR3, the parameter WRBUSY will be transitioned to the first logic level (e.g., logic high “1”), and the processor must continuously read the value of the flag WRBUSY, and the synchronization process is considered complete only when the second logic level (e.g., logic low “0”) is read.

If the processor tries to override the value of the parameters PAR1 or PAR3 during the flag of WRBUSY is 1, the change will be ignored in order not to affect the synchronization process and an error warning signal will be issued to notify the processor. This error warning can be implemented by issuing a bus error or an interrupt event. In one of the embodiments, because the parameter PAR2 does not need to be synchronized to the clock domain of the second clock signal CLK_B (the second clock domain), the write pulse signal wrbusy is not transitioned to 1 when the value of the parameter PAR2 is modified.

As mentioned above, through the synchronization status signal(i.e., the write pulse signal wrbusy) the processor does not need to frequently poll each register or signal that needs to be synchronized, and only needs to observe the status of a single write pulse signal wrbusy to know whether the synchronization process is completed, which greatly simplifies the complexity of software design and improves the execution efficiency of the system. In addition, this disclosure provides an error handling mechanism to prevent users from miswriting parameters to be synchronized during synchronization, and notifies users by sending error warning signals, enhancing the stability and reliability of the system.

In another embodiment of the write pulse signal wrbusy, the case that responsive to the parameter length of the control circuit is greater than the length of bits of the processor's operation system is considered. In this case, a single register cannot store the circuit control parameters completely, and the circuit control parameters need to be split and retained in multiple register banks. In this embodiment, a mechanism is proposed whereby multiple register banks share a synchronous status signal, the write pulse signal wrbusy to ensure that the content of the multiple register banks can be synchronously updated to the second clock domain.

See Table 2, which shows an example of two register banks sharing a flag WRBUSY. In this example, the two register banks (register bank 0 and register bank 1) are used to store a circuit control parameter, PAR, which is 40 bits long, exceeding the number of bits of the processor's operation system (e.g., 32 bits). Therefore, the parameter PAR1 is split into two parts, which are retained in 0 to 31 in register bank 0 and 0 to 7 in register bank 1.

TABLE 2
register bank 1

| 31 | 30 | 29 | 28 | 27 | 26 | 25 | 24 |
|---|---|---|---|---|---|---|---|
| WRBUSY | retention | | | | | | |
| 23 | 22 | 21 | 20 | 19 | 18 | 17 | 16 |

retention

| | | | | | | | |
|---|---|---|---|---|---|---|---|
| 15 | 14 | 13 | 12 | 11 | 10 | 9 | 8 |

retention

| | | | | | | | |
|---|---|---|---|---|---|---|---|
| 7 | 6 | 5 | 4 | 3 | 2 | 1 | 0 |

PAR1
register bank 0

| | | | | | | | |
|---|---|---|---|---|---|---|---|
| 31 | 30 | 29 | 28 | 27 | 26 | 25 | 24 |

PAR1

| | | | | | | | |
|---|---|---|---|---|---|---|---|
| 23 | 22 | 21 | 20 | 19 | 18 | 17 | 16 |

PAR1

| | | | | | | | |
|---|---|---|---|---|---|---|---|
| 15 | 14 | 13 | 12 | 11 | 10 | 9 | 8 |

PAR1

| | | | | | | | |
|---|---|---|---|---|---|---|---|
| 7 | 6 | 5 | 4 | 3 | 2 | 1 | 0 |

PAR1

When the user modifies the content of the parameter PAR1 part of the register bank 0, the corresponding synchronization status flag (i.e., WRBUSY shown in Table 2) is transitioned to the first logic level (e.g., logic high “1”). However, in this case, the write pulse signal wrbusy of the corresponding circuit in the system does not immediately drive the synchronization process, but waits for part of the parameter PAR1 in the register bank 1 to be modified, then the write pulse signal wrbusy is transitioned to the first logic level (e.g., logic high “1”), and then the synchronization process is started. In other words, in the present embodiment, the content of the parameter PAR1 in both the register bank 0 and the register bank 1 need to be modified before the synchronization process is triggered.

In one of the embodiments, if the user only wants to modify the content of register bank 0 and keep the content of register bank 1 unchanged, the user still needs to rewrite the same value to register bank 1 as before, so as to indicate that the user confirms that the same value is to be maintained in register bank 1. This design ensures that all relevant register banks are updated, avoiding data inconsistencies caused by some registers being updated while others are not.

In this embodiment, there is no specific restriction on the order in which the register bank 0 and the register bank 1 are written, and can be determined according to the user's operation. As soon as both register banks are written, the synchronization operation is initiated. After the synchronization is complete, the system will clear the write pulse signal wrbusy to the second logic level (e.g. logic low “0”) through a clear busy signal clr_busy. At this time, the processor may know whether the synchronization process is completed by polling the status of the write pulse signal wrbusy.

As mentioned above, the mechanism of sharing synchronization status signals (flags) across multiple register banks ensures that synchronization can still be performed correctly and efficiently when the parameter length is larger than the length of the bits of the processor's operation system. By waiting for all relevant register banks to be written before triggering synchronization, unexpected error behavior in the controlled circuit due to transient control values can be avoided, further improving the stability and reliability of the system when processing long parameters.

However, as mentioned earlier, a simple polling mechanism, while simple to implement, consumes processor resources to continuously read and acknowledge the synchronization status signal, the write pulse signal wrbusy. In order to solve this problem, this disclosure further proposes an embodiment that integrates a scheduler in the R/W controller to automate the writing and synchronization process of the management of registers.

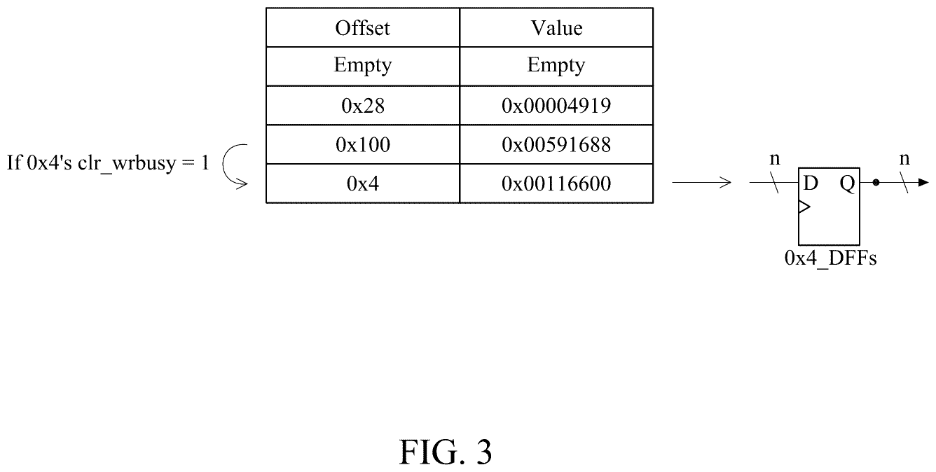

In this embodiment, when the user wants to modify the register value, it is not directly written to the target register, but the register address and/or its offset value and the corresponding write value are stored in the scheduler first. The scheduler has a predetermined capacity to sequentially store multiple pending writes/syncs. For example, the scheduler can be designed to have four register banks of storage space, as shown in FIG. 3.

FIG. 3 is a schematic diagram of the scheduler with a register according to the present disclosure of an embodiment.

Referring to FIG. 3, the scheduler in this example has four register banks, but is not limited to. The scheduler stores three pending write/sync operations in order: a register bank that writes 0x00116600 to the address 0x4, a register bank that writes 0x00591688 to the address 0x100, and a register bank that writes 0x00004919 to the address 0x28. The scheduler executes these operations sequentially on a first-in-first-out basis.

Following the example above, the scheduler will first write the 0x00116600 to the flip-flop (0x4_DFFs) at the address 0x4, and wait for the corresponding clear busy signal clr_busy to be generated (e.g. a pulse or a specific logic level) to confirm that the synchronization operation of the data is complete. The scheduler moves the write operation of the address 0x100 to the first priority and execute the write and synchronization operations of 0x00591688 only after the clear busy signal clr_busy of address 0x4 appears, and so on.

In order to enhance the flexibility and convenience of use, the scheduler of the present embodiment provides the following functions:

Scheduler Clear Status Flag: This flag indicates if there are no more pending writes/syncs in the scheduler and can be used to determine if all syncs have completed.

Event Full Status Flag: This flag indicates whether the scheduler's storage is full. When the scheduler is full, new write/sync schedule items can no longer be added.

Schedule Scheduler Error status Flag: If you try to add a new schedule item while the scheduler is full, the scheduler will issue this error status flag to warn the users.

Schedule error status information: When the scheduler sends an error status flag, it will record the register address of the current error and the value to be written at the same time, so that the user can perform debug or rewrite operations in the future.

Scheduler Enable Control: Users can decide whether to enable the scheduler based on actual application requirements. If the execution sequence of the program does not have strict timing requirements of the synchronization operation, the scheduler can be turned off to save system resources. In one of the embodiments, after the scheduler is closed, the order in which the writing jobs are written may be random, parallel processing, or skipping to the processing that can be completed first and ordered according to this priority rule, etc., but is not limited to.

Scheduled Interrupt Event: The scheduler of this embodiment has a system interruption function. The aforementioned status flags (e.g., clear, full, error, etc.) can be controlled by independent interrupt enable control bits to determine whether or not to send a corresponding interrupt signal to the processor when the flag is set (e.g., set to logic high).

As mentioned above, the read/write controller of the scheduler is integrated to automate the management of register writes and synchronizations. With the scheduler, the processor does not need to continuously poll for synchronization status signals, and can use resources to perform other tasks, greatly improving the overall performance of the system. The status flags and interrupt functions of the scheduler further simplify the complexity of software development and improve the stability and reliability of the system. In addition, users can selectively enable the scheduler according to their application needs, providing greater flexibility and configurability.

In summary, this embodiment can effectively solve the shortcomings existing in prior art, and greatly improve the system efficiency and stability.

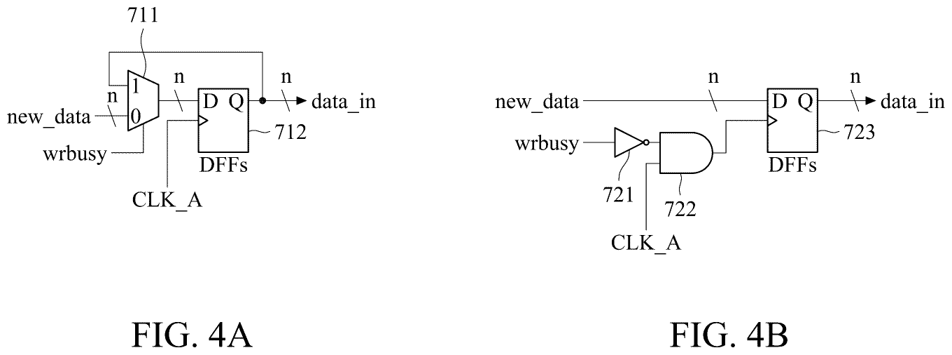

Following the above, in order to ensure the correctness of data synchronization, when the synchronization operation is in progress (i.e., when the synchronization status signal, write pulse signal wrbusy, is the first logic level, such as the high standard “1”), it is necessary to avoid modifying the data signal data_in corresponding to a register bank. This disclosure further proposes two embodiments as shown in FIG. 4 to prevent the data from being mistakenly altered during the synchronization process, which are described below.

FIG. 4A is a schematic diagram of a circuit architecture with a write ignore mechanism, and FIG. 4B is a schematic diagram of a circuit architecture with a bus control mechanism.

In the embodiment of FIG. 4A, the status of the signal wrbusy can be determined by a logic circuit to decide whether to write new data new_data to the corresponding register. As shown in of FIG. 4A, when wrbusy=“1”, the synchronization process is in progress, and the logic circuit ignores the new input data new_data and maintains the value of the original data signal data_in to avoid changing the data being synchronized.

In this embodiment, users may know the current synchronization status by reading and polling the value of the synchronization status signal(i.e., write pulse signal wrbusy). When write pulse signal wrbusy is high level, the user should avoid updating the value of the corresponding register bank as the update will be ignored.

In one of the embodiments, if the semiconductor device already has a mechanism of “a R/W controller with a scheduler” as in the preceding embodiment, the circuit shown in FIG. 4 is not necessary because the scheduler will perform the next synchronization process when the write pulse signal wrbusy is the second logic level (e.g., low level “0”).

In the embodiment of FIG. 4B, when the write pulse signal wrbusy corresponding to a register bank is the first logic level (e.g., high logic level “1”), if the user modifies the value of the register bank again, the system enters a waiting state for the control bus to pause data transmission to wait for the synchronization operation to complete.

In one of the embodiments, the advanced high-performance bus (AHB) protocol, for example, this bus control mechanism can be implemented through the control signal HREADY. When the write pulse signal wrbusy is high level, the system maintains the signal HREADY at a logic low, indicating that the bus is not ready and the data transmission needs to be paused. When the synchronizer completes the synchronization task and pulls the wrbusy signal back to the second logic level (e.g., low level “0”), the system will convert the signal HREADY to logic high, indicating that the bus is ready to continue data transmission.

Although this mechanism prevents the processor from frequently polling the status of the write pulse signal wrbusy, the access operation of the processor will still be suspended during the synchronization operation, which may affect the system performance.

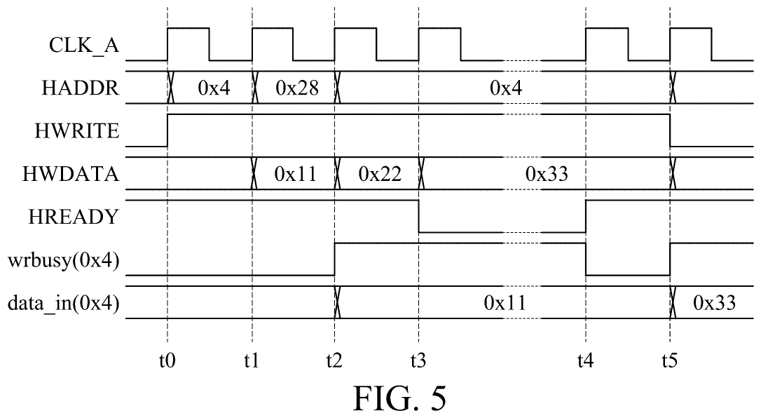

FIG. 5 shows a sequence diagram illustrating the operation principle of bus control mechanism.

In one of the embodiments, the processor wants to modify a particular register address multiple times in the following order: address 0x4 write to 0x11, address 0x28 write to 0x22, address 0x4 write to 0x33. At time t0, the processor issues a write command to the address 0x4 (control phase); at time t1, the processor transmits the data 0x11 to be written (data phase), and the system also issues a write command to the address 0x28 (control phase). At time t2, the processor transmits the data 0x22 (data phase) to be written to the address 0x28. Since the address 0x4 and 0x28 belong to different register banks, and assuming that the corresponding signal wrbusy is “0” in the initial state, the write operation of these two data can be executed smoothly, and the signal HREADY maintains in high level during this period, indicating that the data transmission is normal.

However, at time t2, the processor issues a second write command to the address 0x4 to update the value of address 0x4 to 0x33. In this case, because the data (0x11) written to the address in the first address 0x4 has not yet been synchronized (the corresponding write pulse signal wrbusy is still at a high level), in order to avoid data errors, the system must suspend the second write operation to the address 0x4. Therefore, at time t3 (i.e., the data phase of the second time writing to the address 0x4), the system pulls the signal HREADY to a logic low and pauses the bus transmission.

It is not until time t4 that the first data (0x11) written to the address 0x4 is synchronized, and the corresponding signal wrbusy is converted to logic low, and the system converts the signal HREADY back to logic high, indicating that the bus transmission restores to normal. Then, at time t5, the system updates the input signal data_in to 0x33, and pulls the corresponding signal wrbusy to logic high again, and starts the second synchronization operation to the address 0x4.

Through the above-mentioned mechanism to prevent data error during the synchronization process, the correctness and reliability of data synchronization are ensured. Through the write ignore mechanism or bus control mechanism, it can effectively avoid the user from writing the register bank that is being synchronized, resulting in synchronization data errors or system operation abnormalities. In addition, the bus control mechanism temporarily interrupts the access and access operations of the processor, but prevents the processor from frequently polling for synchronization status signals, thereby improving the overall performance of the system.

In addition, in order to solve the problem of loss of synchronizer data due to power-off in the power supply region of prior art techniques, a multi-bit synchronizer circuit architecture with multi-power supply region data retention function is provided, as shown in FIG. 5. This architecture can be applied to semiconductor devices with multiple power supply regions, and when the system enters power-saving mode, the state value of the synchronizer is retained, and when the system wakes up, the state value is retained to the synchronizer to ensure the correct operation of the back-end circuitry.

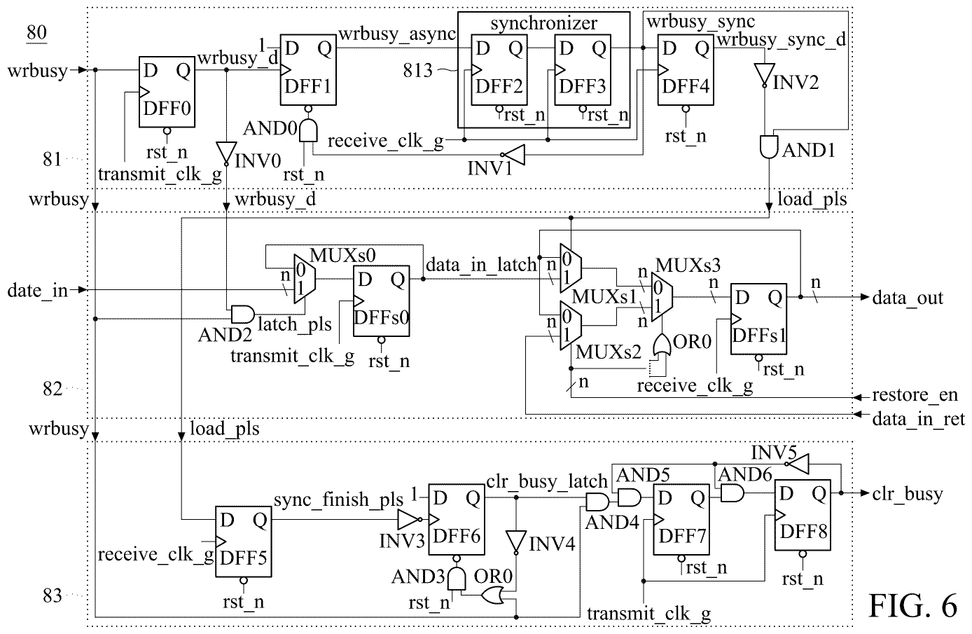

FIG. 6 illustrates the circuit architecture of a multi-bit synchronizer with a multi-power supply region data retention function.

As shown in FIG. 6, the multi-bit synchronous circuit 80 with the data retention function of multiple power supply regions includes: a synchronization control circuit block 81, a data retention cell block 82, and a state control circuit block 83, wherein the synchronization control circuit block 81 comprises a synchronizer 813.

Compared with a prior art multi-bit synchronizer shown in FIG. 2, the circuit architecture of the multi-bit synchronous circuit 80 disclosed herein further includes a data retention signal data_in_ret and a restore enable signal restore_en to implement the data retention and restore functions of multiple power supply regions. In addition, the description of components similar to the prior art multi-bit synchronizer shown in FIG. 2 is omitted.

In one of the embodiments, the data retention signal data_in_ret connected to another power supply region which is different from the power supply region where the synchronizer 813 is located, and is used for storing the state value of the output signal data_out of the synchronizer 813 before the system enters power-saving mode. After the system wakes up, because the synchronizer 813 will lose its original state value due to power-off, the value of the data retention signal data_in_ret needs to be restored to the output signal data_out, so as to avoid affecting the operation of the back-end circuit.

In one of the embodiments, the restore enable signal restore_en is used to control the data restoration function. Since a system may be divided into multiple power supply regions, there will be different combinations of the power-off power supply regions in different power-saving modes. Therefore, it is necessary to determine the data retention function of each bit in the synchronizer 813 by restore enable signal restore_en, and only recover the bits of the data retention signal data_in_ret from the power supply region that has not been powered off.

In one of the embodiments, an input terminal (“1”) of the multiplexer MUXs2 in the data retention cell block 82 receives a data retention signal data_in_ret. A control terminal of the multiplexer MUXs3 in block 82 of the data storage element receives a restore enable signal restore_en. When the system enters power-saving mode, the first power supply region where the synchronizer 813 is located (e.g., the first power supply region VDD0 shown in FIG. 1) is powered off, and the data retention signal data_in_ret is provided by the second power supply region (e.g., the second power supply region VDD1 shown in FIG. 1) that is not powered off.

In one of the embodiments, when the system wakes up, the first power supply region restores the power supply, at this time, if the restore enable signal restore_en is the first logic level (e.g., logic high “1”), then the multiplexer MUXs3 will select the output (i.e., data retention signal data_in_ret) of the multiplexer MUXs2 as the output, and transmit the output to the data input terminal D of the flip-flop DFFs1 to restore the value of data signal data_in_ret to the output signal data_out.

In one of the embodiments, if the restore enable signal restore_en is the second logic level (e.g., logic low “0”), the multiplexer MUXs3 selects its input terminal “0” (i.e., the output terminal of the signal MUXs1) as the output, keeping the value of the output signal data_out unchanged.

In more detail, the synchronous control circuit block 81 includes: a first flip-flop DFF0 and an inverter INV0, which are used to generate a delayed write pulse signal wrbusy_d based on the write pulse signal wrbusy (e.g., from a register controller). In one of the embodiments, the write pulse signal wrbusy is coupled to the data input terminal D of the first flip-flop DFF0, and the output terminal of the first flip-flop DFF0 outputs the delayed write pulse signal wrbusy_d, coupled to the clock input terminal of the second flip-flop DFF1, and is also coupled to the input terminal of the inverter INV0. The write pulse signal wrbusy can be used to indicate whether there is data from an external circuit (e.g., CPU or read/write controller) that needs to be written to the synchronizer 813.

In one of the embodiments, the data retention cell block 82 includes an AND gate AND2, a multiplexer MUXs0 and a flip-flop DFFs0. One input terminal of the AND gate AND2 receives the write pulse signal wrbusy, and another input terminal receives the inverted signal, delayed write pulse signal wrbusy_d, which is output by the inverter INV0. The output signal latch_pls of the AND gate AND2 is coupled to the control terminal of the multiplexer MUXs0.

In one of the embodiments, the first input terminal (terminal “0”) of the multiplexer MUXs0 is coupled to the output terminal Q of the flip-flop DFFs0; the second input terminal (terminal “1”) of the multiplexer MUXs0 receives the data signal data_in from the external input; the output terminal of the multiplexer MUXs0 is coupled to the input terminal D of the flip-flop DFFs0, and the control terminal of the flip-flop DFFs0 receives the latch pulse signal latch_pls.

In one of the embodiments, the clock input terminal of the flip-flop DFFs0 receives a gated transmitter clock signal transmit_clk_g (e.g., first clock signal CLK_A). The output terminal Q of the flip-flop DFFs0 outputs the latched data signal data_in_latch. The latch pulse signal latch_pls is generated by the output of the AND gate AND2 to control the update of the data signal data_in_latch.

In one of the embodiments, the synchronizer 813 includes multiple series connected flip-flops (flip-flop DFF1, flip-flop DFF2, flip-flop DFF3, flip-flop DFF4), and inverters (inverter INV1, inverter INV2) and AND gates (AND gate AND0, AND gate AND1). The data input terminal D of the flip-flop DFF1 receives the first logic level (such as logic high “1”), and the output signal, delayed write pulse signal wrbusy_d, of the flip-flop DFF0 coupled to the clock input terminal of the flip-flop DFF1, and the data input terminal D of the remaining flip-flops (flip-flop DFF2, flip-flop DFF3, and flip-flop DFF4) are coupled with the output terminal Q of the previous flip-flop respectively. The clock input terminal of the flip-flops (flip-flop DFF2, flip-flop DFF3, and flip-flop DFF4) receives a gated receiver clock signal receive_clk_g (e.g., second clock signal CLK_B). The output terminal Q of the flip-flop DFF1 outputs signal wrbusy_async. The output terminal Q of the flip-flop DFF3 outputs the write synchronous signal wrbusy_sync; the output terminal Q of the flip-flop DFF4 outputs delayed write synchronous signal wrbusy_sync_d and coupled to the input terminal of the AND gate AND1 through the inverter INV2. Another input terminal of AND gate AND1 is coupled to the write synchronous signal wrbusy_sync. The output terminal of the AND gate AND1 outputs load pulse signal load_pls.

In one of the embodiments, the write synchronous signal wrbusy_sync may also pass through a delay circuit (e.g., consisting of at least one inverter) to generate a delayed write synchronous signal wrbusy_sync_d.

In one of the embodiments, the data retention cell block 82 includes multiplexers (multiplexer MUXs1, multiplexer MUXs2, multiplexer MUXs3) and a flip-flop DFFs1.

In one of the embodiments, the first input terminal (terminal “0”) of the multiplexer MUXs1 receives the data signal data_out, and the second input terminal (terminal “1”) is coupled to receive a latched data signal data_in_latch; The control terminal receives the load pulse signal load_pls, and the output terminal is coupled to the first input terminal (terminal “0”) of the multiplexer MUXs3.

In one of the embodiments, the first input terminal (terminal “0”) of the multiplexer MUXs2 receives an output signal data_out, the second input terminal (terminal “1”) receives the data retention signal data_in_ret, the control terminal receives a restore enable signal restore_en, and the output terminal is coupled to the second input terminal (terminal “1”) of the multiplexer MUXs3.

In one of the embodiments, the control terminal of the multiplexer MUXs3 is coupled to the output terminal of an OR gate. The output terminal of the multiplexer MUXs3 is coupled to the data input terminal D of the flip-flop DFFs1.

In one of the embodiments, the clock input terminal of the flip-flop DFFs1 receives the gated receiver clock signal receive_clk_g, and the output terminal Q output data signal data_out.

In one of the embodiments, the state control circuit block 83 includes flip-flops (flip-flop DFF5, flip-flop DFF6, flip-flop DFF7, flip-flop DFF8), inverters (inverter INV3, inverter INV4, inverter INV5) and AND gates (AND gate AND3, AND gate AND4, AND gate AND5, AND gate AND6), but is not limited to.

In one of the embodiments, the data input terminal D of the flip-flop DFF5 receives the signal load_pls, the clock input terminal receives the gated receiver clock signal receive_clk_g, and the output terminal Q outputs the synchronous finish pulse signal sync_finish_pls.

In one of the embodiments, the clock input terminal of the flip-flop DFF6 receives the synchronous finish pulse signal sync_finish_pls through the inverter INV3. The output terminal Q of the flip-flop DFF6 is coupled to the data input terminal D of the flip-flop DFF7 through the AND gate AND4.

In one of the embodiments, the reset terminal of the flip-flop DFF6 is coupled to an AND gate AND3, and the input terminal of the AND gate AND3 receives the signal rst_n, another input terminal is coupled to the output terminal of the inverter INV4, and the output terminal of the AND gate AND3 is coupled to the reset terminal of the flip-flop DFF6.

In one of the embodiments, the clock input terminal of the flip-flop DFF7 receives the gated transmitter clock signal transmit_clk_g. The output terminal Q of the flip-flop DFF7 is coupled to the data input terminal D of the flip-flop DFF8 through the AND gate AND6. The clock input terminal of the flip-flop DFF8 receives the gated transmitter clock signal transmit_clk_g. The output terminal Q of the flip-flop DFF8 outputs the clear busy signal clr_busy, and is coupled to an input terminal of the AND gate AND5 and AND gate AND6 through the inverter INV5.

Through the above-mentioned multi-bit synchronizer circuit architecture with multi-power supply region data retention function, ensures that the synchronizer can still effectively retain the state value when the system enters the power-saving mode, and correctly restore to the previous state after the system wakes up. Through the design of data retention signal (data_in_ret) and restore enable signal, this disclosure can be applied to complex multi-power supply region systems, and the bits that need to be retained and restored can be flexibly selected for different power-saving modes, which improves the flexibility of system design. In addition, the circuit architecture disclosed herein maintains the state of the output signal by maintaining the circuit (e.g. data retention cell block) during the synchronization process, which ensures that the output value of the synchronizer remains unchanged during the power-off period even if the synchronizer is located in the power supply region that will be powered off, preventing the back-end circuit from operating improperly due to receiving the preset value, and avoiding frequent polling by the processor, further improving the system performance.

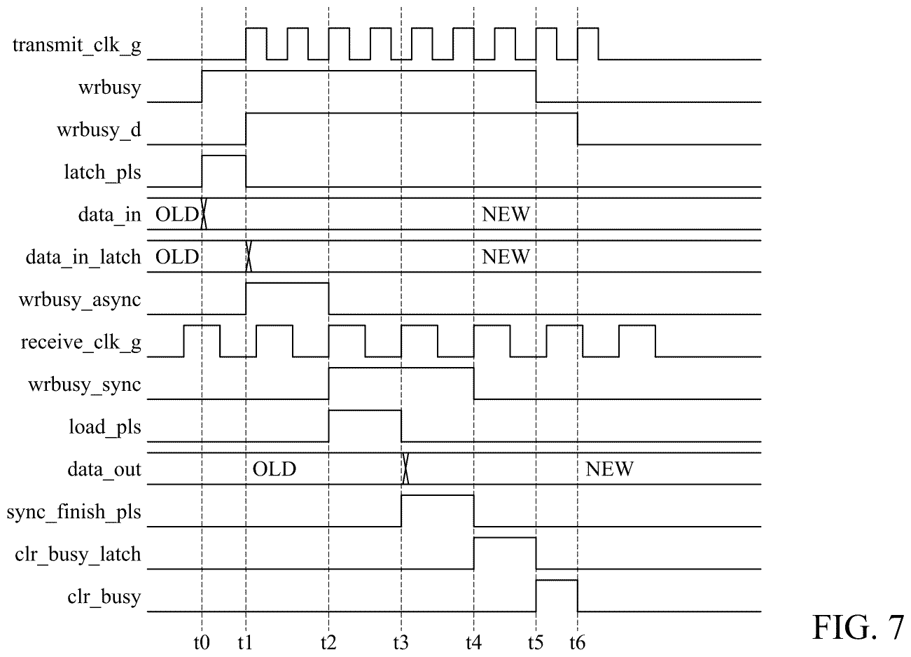

FIG. 7 shows a timing diagram of the multi-bit synchronous circuit in FIG. 6 when data is synchronized.

FIG. 7 shows the signal waveform of a multi-bit synchronizer with a multi-power supply region data retention function during data synchronization, and shows the timing relationship of each important signal during the synchronization process. In this embodiment, since only the synchronization task is performed and no data restoration is involved, the restore enable signal restore_en is maintained at a logic low in this scenario.

In one of the embodiments, at time t0, the value of the input data signal data_in changes from OLD to NEW, and the write pulse signal wrbusy is transitioned from logic low to logic high, indicating that a new data needs to be synchronized. The write pulse signal wrbusy passes through the first flip-flop DFF0 and generates an internal signal, delayed write pulse signal wrbusy_d. Then, the delayed write pulse signal wrbusy_d pass through the inverter INV0 and the AND gate AND2 to generate a periodic latch pulse signal latch_pls.

In one of the embodiments, at time t1, the latch pulse signal latch_pls is logic high, so that the multiplexer MUXs0 in the data retention cell block 82 selects the input terminal “1” as the output, transmits the new value (NEW) of the input data signal data_in to the data input terminal D of the flip-flop DFFs0, and when the next rising edge of the gated transmitter clock signal transmit_clk_g triggered, the new value is latched to the output terminal Q of the flip-flop DFFs0, and the latched data signal data_in_latch is generated. At the same time, the signal wrbusy_async transitioned to logic high.

In one of the embodiments, in the interval between time t1 and time t2, the signal wrbusy_async is synchronized to the clock domain of the receiver clock signal receive_clk (e.g., second clock signal CLK_B) through a synchronizer composed of the third flip-flop DFF2 and the fourth flip-flop DFF3, and the write synchronous signal wrbusy_sync is generated.

In one of the embodiments, at time t2, the write synchronous signal wrbusy_sync is converted to logic high, on the one hand, the feedback clear signal wrbusy_async is logic low, and on the other hand, a periodic load pulse signal load_pls is generated through the inverter INV2 and the AND gate AND1.

In one of the embodiments, at time t3, the load pulse signal load_pls is logic high, so that the multiplexer MUXs3 in the data retention cell block 82 selects its input terminal “0” as the output, and transmits the latched data signal data_in_latch (which has been the new value NEW at this time) to the data input terminal D of the flip-flop DFFs1, and is triggered by the next rising edge of the gated receiver clock signal receive_clk_g. The new value is latched to the output terminal Q of the flip-flop DFFs1 to generate a synchronized data signal data_out. At this time, the new value of the data signal data_in NEW has been successfully synchronized to the receiver clock domain. Since the period of time t1-t3 is enough for the signal to be transmitted from the output terminal Q of the flip-flop DFFs0 to the data input terminal D of the flip-flop DFFs1, the data signal data_in can be successfully synchronized to the gated receiver clock signal receive_clk_g through the process before the time t3.

In one of the embodiments, the main purpose of the process after time t3 is to clear the write pulse signal wrbusy and restore the synchronizer to a state ready to accept the next synchronization task. At time t3, a synchronous finish pulse signal sync_finish_pls is transitioned from logic low to logic high. The synchronous finish pulse signal sync_finish_pls is output by the flip-flop DFF5, and after passing through the inverter INV3, it is provided to the clock input terminal of the flip-flop DFF6, so that the output terminal Q of the flip-flop DFF6 generates a signal clr_busy_latch. The reason for the need for the inverter INV3 is that it is necessary to ensure that the clear busy signal clr_busy used to clear the signal wrbusy does not appear until the write synchronous signal wrbusy_sync is transitioned to logic low, so as to avoid clock domain crossing between the reset terminal of the second flip-flop DFF1 and the clock input terminal.

In one of the embodiments, at time t4, the clear busy signal clr_busy_latch is transitioned to logic high. The signal clr_busy_latch is synchronized to the clock domain (CLA_A) of the transmitter clock signal (transmit_clk_g) through the synchronizer composed of flip-flop DFF7 and flip-flop DFF8, and generates a period logic high signal, clear busy signal clr_busy.

In one of the embodiments, the signal clr_busy_latch must be cleared before time t6, otherwise it is possible to generate two pulses of clear busy signal clr_busy, resulting in an error. The transmission path from clear busy signal clr_busy to the write pulse signal wrbusy to signal clr_busy_latch is transmitted through the asynchronous path of the flip-flop.

In order to ensure the correctness of the timing and avoid the problem of timing domain switching, this disclosure uses logic circuits such as the synchronization gate to force the establishment of a path that can be analyzed by static timing analysis tools, and limits the transmission delay to one period of the gated transmitter clock signal transmit_clk_g. In the state control circuit block 83, the same mechanism is used for the path of processing the signal clr_busy_latch through the AND gate AND4.

Following the above, the waveform shown in FIG. 7 clearly shows the timing relationship between the individual signals and how the synchronizer correctly transfers data between different clock domains, ensuring the accuracy and reliability of data synchronization through precise timing control and data latch mechanisms.

In addition, the clock domain crossing between the reset terminal of the second flip-flop DFF1 and the clock input terminal is avoided by setting the inverter INV3. The use of circuits such as AND gate AND4 to establish a path that can be analyzed by static timing analysis tools ensures the stability of the circuit at high-speed operation and reduces the risk of timing domain switching problems.

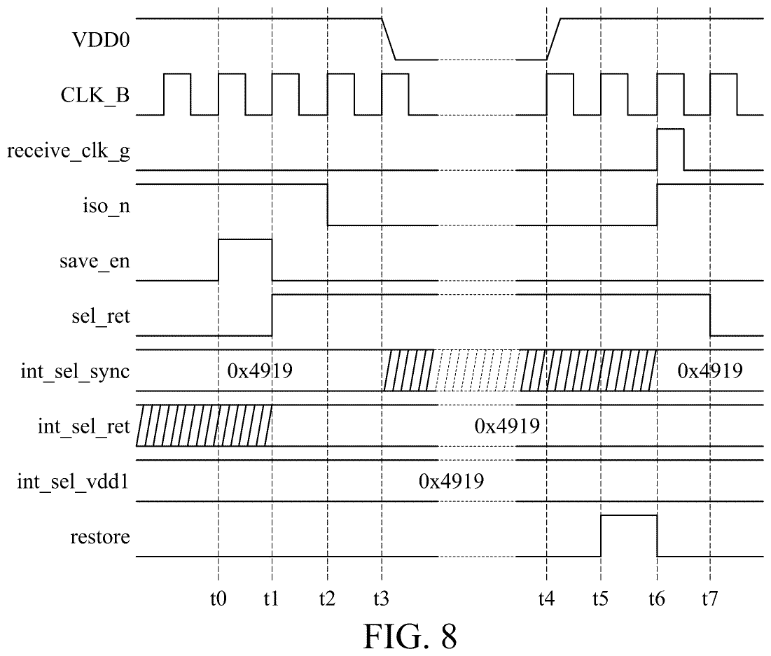

FIG. 8 shows the waveform of the multi-bit synchronizer in the multi-bit register synchronization control system with multi-power supply region data retention function when entering and leaving the power-saving mode.

In one of the embodiments, the waveform diagram of FIG. 8 can be used to illustrate the operation in the preceding multi-bit synchronizer circuit architecture. Through the waveform diagram in FIG. 8, it can be clearly understood that the timing changes of each important signal and the specific process of data retention and restore during the power-saving mode switching process.

In this embodiment, the data retention and restore functions of multiple power supply regions are implemented through a data retention signal int_sel_ret and a restore enable signal restore. Wherein, the data retention signal int_sel_ret connected to another power supply region, second power supply region VDD1, which is different from the first power supply region VDD0 where the synchronizer is located, and is used to store the state value of the output signal data_out (i.e., synchronous output signal int_sel_sync) of the synchronizer before the system enters the power-saving mode.

Referring to FIG. 8, at time t0, a save enable signal save_en is transitioned to logic high, and the value of the synchronous output signal int_sel_sync of the synchronizer (assumed to be 0x4919 at this time) is ready to be retained to the second power supply region VDD1.

At time t1, the value of the synchronous output signal int_sel_sync has been retained to the data retention signal int_sel_ret, and the selection signal sel_ret is transitioned from logic low to logic high. At this time, the signal source of an output signal int_sel_vdd1 is switched from the synchronous output signal int_sel_sync to the data retention signal int_sel_ret, so that the value of the output signal int_sel_vdd1 is updated to the value retained by the data retention signal int_sel_ret (i.e., 0x4919).

At time t2, the system initiates the isolation mechanism of the isolation cell. At this moment, an isolation signal iso_n is transitioned from logic high to logic low, so that the isolation cell forcibly sets its output to a predetermined logic level (such as logic low), thereby blocking the signal of the first circuit block (such as the circuit located in the first power supply region VDD0), and avoiding having an influence on the operation of the second circuit block (such as the circuit located in the second power supply region VDD1).

At time t3, the system power off the first power supply region VDD0, and the value of the synchronous output signal int_sel_sync of the synchronizer may change to an undefined state (represented by a diagonal line in FIG. 8), but the undefined state does not affect the signal int_sel_vdd1 due to the effect of the isolation cell. At this time, the procedure for retaining the synchronized values has been completed.

At time t4, the system is woken up, and the first power supply region VDD0 starts to power on and the power supply is retained.

At time t5, the system sends a restore signal restore (e.g., a pulse signal) and restore the value of the signal int_sel_ret (i.e., 0x4919) to the synchronous output signal int_sel_sync of the synchronizer. At this time, the data input terminal D of the flip-flop inside the synchronous circuit receives the output from the multiplexer, and its value is data retention signal data_in_ret (i.e., the value of the data retention signal int_sel_ret). When triggered by the signal restore, the synchronizer latches the value of the data retention signal int_sel_ret to its output to complete the data restoration.

At time t6, the value of the synchronous output signal int_sel_sync has completed restoration and its value becomes the same as the signal int_sel_ret (i.e., 0x4919). At this time, the system turns off the isolation mechanism of the isolation cell, that is, the isolation signal iso_n is transitioned from the logic low to logic high, and the blocking of the signal of the first circuit block is removed.

At time t7, the selection signal sel_ret is transitioned from logic high to logic low, so that the signal source of the output signal int_sel_vdd1 is switched back to the synchronous output signal int_sel_sync by the data retention signal int_sel_ret. At this time, the synchronous output signal int_sel_sync of the synchronizer has retained to the state before entering the power-saving mode (0x4919), and the signal source with the output signal int_sel_vdd1 has also been switched back to the output terminal of the synchronizer. The restoration for synchronizing values is complete.

The output signal int_sel_vdd1 remains at the default value 0x4919 throughout the power-saving mode entry and exit, ensuring that the back-end circuitry (e.g. timer) operates according to the correct configurations during the system entering and exiting the power-saving mode.

As mentioned above, through the above data retention mechanism, it can ensure that the state value of the synchronizer can still be properly retained when the system enters the power-saving mode, which solves the problem of synchronizer data loss due to power-off in the power supply region in prior art. After the system wakes up, through the above-mentioned data restoration mechanism, the retained state value can be correctly retained to the synchronizer, so as to ensure that the back-end circuit can continue to operate according to the correct configurations after the system wakes up, and avoid the abnormal operation of the circuit caused by the wrong configuration.

In addition, this disclosure ensures the reliability of the data retention and response process through precise timing control. The waveform shown in FIG. 8 clearly shows the timing relationship between the individual signals and how the signal changes at different stages. Through the design of this disclosure, it can be applied to a variety of complex multi-power supply region systems, and flexibly select the bits that need to be retained and restored for different power-saving modes.

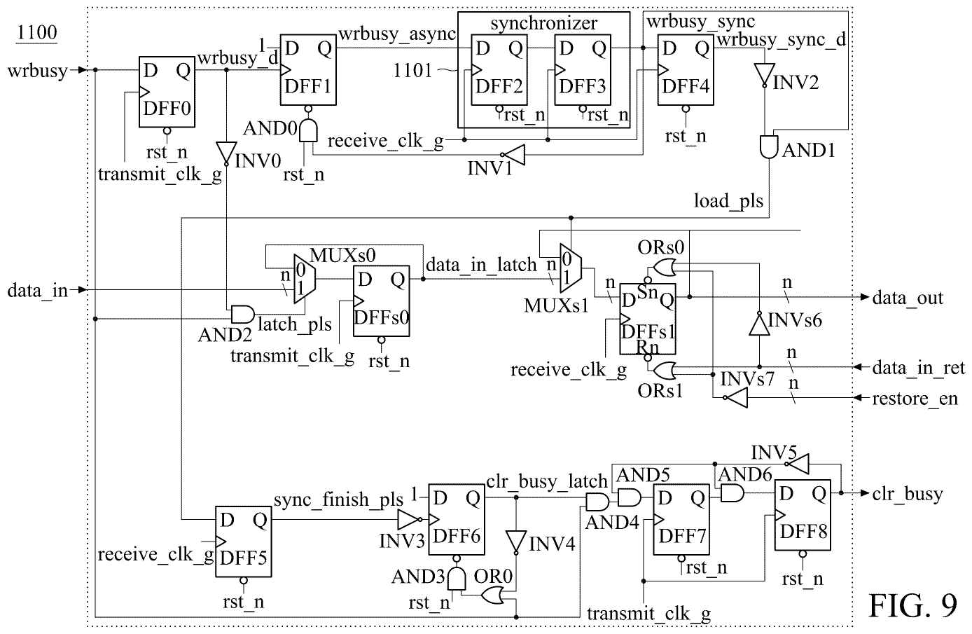

FIG. 9 is a schematic diagram of the multi-bit synchronous circuit architecture with the multi-power supply region data retention function according to one of the embodiments in this disclosure.

In order to further improve the performance of the synchronizer and simplify the data restoration mechanism, a multi-bit synchronous circuit architecture with multi-power supply region data retention function is proposed as shown in FIG. 9. Compared with the embodiment shown in FIG. 6, the circuit architecture of FIG. 9 removes the multiplexer MUXs2 and multiplexer MUXs3, and uses the reset terminal Rn of the flip-flop DFFs1 to carry out asynchronous control with the setting terminal Sn to implement the restoration of the data retention value.

In FIG. 9, the multi-bit synchronous circuit 1100 mainly includes: a synchronous control circuit block with a synchronizer 1101, a data retention cell block and a state control circuit block. Wherein, detailed descriptions of parts identical to those in FIG. 6, that is, the composition and connection relationship of the synchronous control circuit block, the data retention cell block and the state control circuit block, are omitted, and the difference is that in the present embodiment, the multiplexer MUXs2 and multiplexer MUXs3 in FIG. 6 are removed from the output part.

In this embodiment, the asynchronous data restoration is implemented through the reset terminal Rn of the flip-flop DFFs1 and the setting terminal Sn. Compared with the embodiment in FIG. 6, the multiplexer MUXs2 and multiplexer MUXs3 are removed in this embodiment, so that the path of the data signal data_in_latch to the output signal data_out of the synchronizer is more concise, and the upper frequency limit of the target clock domain of the synchronizer can be effectively increased. In addition, the power consumption of the system is further reduced by eliminating the need for any clock signals during data restoration process.

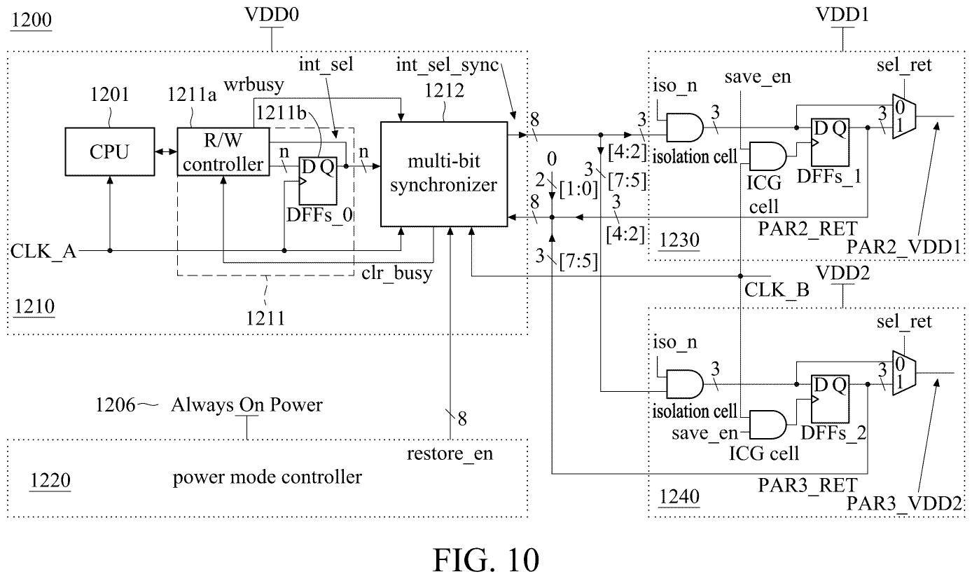

FIG. 10 is a schematic diagram of a semiconductor device that can be applied to a multi-bit synchronizer circuit architecture in a multi-power supply region system according to one of the embodiments in this disclosure.

In one of the embodiments, the semiconductor device 1200 includes three circuit control parameters PAR1, PAR2 and PAR3, which are retained in different bits of a register bank. In this example, the parameters PAR1, PAR2, and PAR3 all need to be synchronized to the second clock domain (e.g., the clock domain of the signal CLK_B). However, when the system wakes up from power-saving mode, the data retention requirements for these three parameters vary from one another.

Specifically, the parameter PAR1 does not need to retain its control values after the system wakes up, so there is no need for additional data restoration circuitry. The control value of the parameter PAR2 needs to be retained in the first power supply region VDD1, so its corresponding register bit signal (e.g., the 2nd through 4th bits) is transmitted to a data retention circuit located under the second power supply region VDD1 for data retention. The data retention circuit feedbacks the retained signal PAR2_RET to the multi-bit synchronizer 1212. The control value of the parameter PAR3 needs to be retained in the third power supply region VDD2, so that the corresponding register bit signal (e.g. the 5th through 7th bits) is transmitted to a data retention circuit located under the third power supply region VDD2 for data retention. The data restoration circuit feedbacks the retained signal PAR3_RET to the multi-bit synchronizer 1212.

In addition, the system further includes a power mode controller 1220, which is usually set up in a power supply region that is always-on powered. This power mode controller is responsible for controlling the state of the individual power supplies in the system, as well as controlling the timing of the isolation signal iso_n, save enable signal save_en, selection signal sel_ret, and restore enable signal restore_en.

As mentioned above, since the value of the parameter PAR1 does not need to be retained, the input bit of the corresponding data retention signal data_in_ret can be fed back directly to logic low “0” to the multi-bit synchronizer 1212. The retained signal PAR2_RET and retained signal PAR3_RET are provided by data retention circuits located in different power supply regions.

When the system enters the power-saving mode, the first power supply region VDD0 is powered off, and the multi-bit synchronizer 1212 stops operating. In this case, the data retention signal data_in_ret will reflect the state of the parameter PAR2 and parameter PAR3 before power-off based on the values of the retained signal PAR2_RET and the retained signal PAR3_RET. When the system wakes up from the power-saving mode, the power supply in the first power supply region is restored, and the flip-flop DFFs1 can be controlled by the restore enable signal restore_en, and the retained value is restored to the multi-bit synchronizer 1212, and then the output signal of the synchronizer is updated.

Compared with prior art, this disclosure removes unnecessary multiplexer components, shortens the data transmission path, and implements a high-performance and low power consumption data retention and restore mechanism through a simple circuit design.

Furthermore, this disclosure provides a flexible multi-power supply region data retention scheme, which can be retained in different power supply regions according to the retention needs of different circuit control parameters, and integrated through a single data retention signal. The design of this disclosure can be applied to a variety of applications that require multi-power supply region management and data synchronization, and has high industrial utilization value.

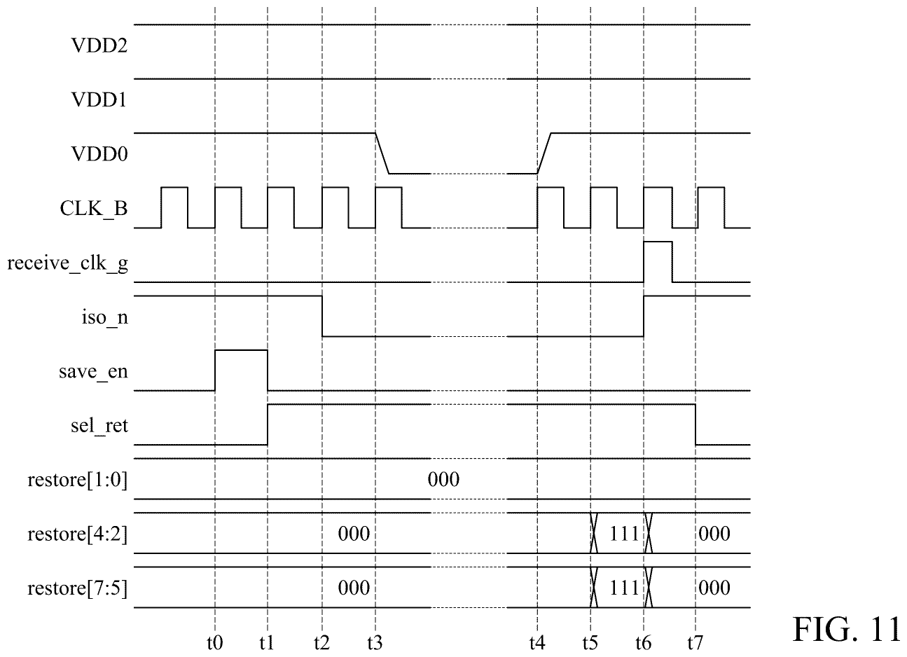

FIG. 11 shows the waveform diagram of the operation of the multi-power supply region data retention and restore mechanism of a semiconductor device in FIG. 10.

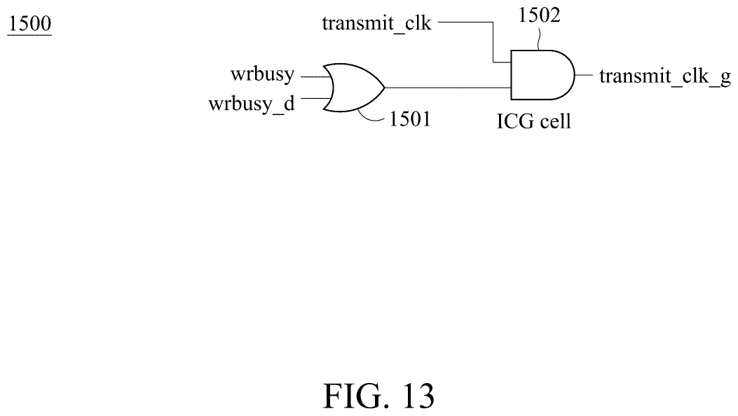

The waveform diagram in FIG. 11 corresponds to the system architecture in FIG. 13 and illustrates the timing variations of each important signal during power-off mode switching. The present embodiment is similar to the embodiment shown in FIG. 8, and the main difference is in the control method of restore enable signal restore.

In the present embodiment, the restore enable signal restore is a multi-bit signal (e.g., restore[7:0]), where each bit corresponds to one bit of the synchronizer output signal data_out. When the system wakes up from the power-saving mode, the power mode controller will control the value of the signal to restore each bit according to the power supply region to which each bit belongs and the configuration of system's power-saving mode.

As shown in FIG. 11, the signal waveforms from t0 to t4 are similar to those in FIG. 8, indicating that the system enters power-saving mode and performs data retention process. At time t4, the system is woken up and the first power supply region VDD0 is powered back on. At time t5, the power mode controller sends a restore enable signal restore to control the data restoration for each bit in the synchronizer.

In this example, it is assumed that the 0th through 1st bits of the register bank (signal restore[1:0]) belong to the parameter PAR1, and that parameter PAR1 does not need to retain its value after the system wakes up. Therefore, the signal restore[1:0] is set to logic low of “00” at time t5, so that the corresponding bit will not perform data restoration.

In one of the embodiments, the 2nd through 4th bits of the register bank (signal restore[4:2]) belong to the parameter PAR2, and the value of the parameter PAR2 needs to be retained in the second power supply region VDD1. Therefore, the signal restore [4:2] is set to logic high “111” at time t5, so that the corresponding bits restores the data retention signal data_in_ret (the value of which comes from the retention circuit in the second power supply region VDD1) to the output signal data_out of the synchronizer.

In one of the embodiments, the 5th through 7th bits of the register bank (signal restore[7:5]) belong to the parameter PAR3, and the value of the parameter PAR3 needs to be retained in the third power supply region VDD2. However, in this example, it is assumed that the current power-saving mode setting of the system will also power off the third power supply region VDD2. Therefore, although the value of the parameter PAR3 should have been retained, the corresponding retention circuit was also in a power-off state, and the correct retained value could no longer be provided. In this case, the power mode controller sets the signal restore[7:5] at time t5 to logic low “000”, so that the corresponding bit does not perform data restoration and maintains its default value. Typically, the default value of the data signal data_out of the synchronizer will be the same as the default value of the register that needs to be synchronized to ensure that the back-end circuit receives the correct initial value after the system wakes up.

Through this bit mask control method, this disclosure can accurately control each bit data response for different power-saving modes and different data retention needs. For example, in another power-off mode, if the third power supply region VDD2 is not powered off, the power mode controller can set signal restore[7:5] to logic high of “111” to restore the value of the parameter PAR3. Through the design of the bit mask, each bit can be independently controlled whether it needs to perform data restoration, which further improves the adaptability and reliability of the system in different power-saving modes.

In addition, this disclosure can dynamically adjust the restore enable signal according to the power-off situation of different power supply regions, so as to avoid errors caused by using the retained value of the power supply region that has been powered off. According to the system's power management strategy, the power mode controller can set the correct value of signal restore when the system wakes up, ensuring that only the data retention signal from the non-powered-off power supply region will be retained to the output terminal of the synchronizer, which further improves the stability and safety of the system.

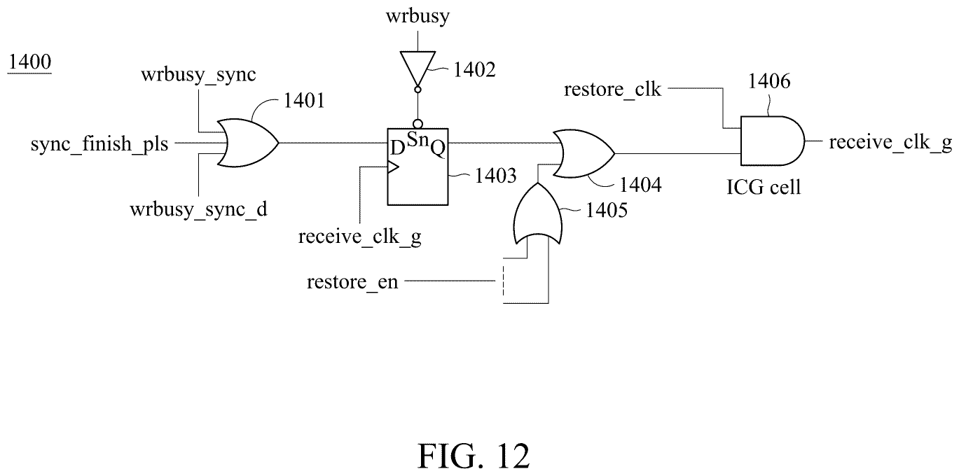

FIG. 12 is a schematic diagram of the clock gating circuit architecture of one of the embodiments in this disclosure.

In order to further reduce the power consumption of the synchronizer, a clock gating circuit architecture as shown in FIG. 12 is proposed to control the gated receiver clock signal receive_clk_g provided to the synchronizer.

In FIG. 12, the clock gating circuit 1400 mainly includes an OR gate 1401, an inverter 1402, a flip-flop (DFF) 1403 with an asynchronous setting terminal Sn, an OR gate 1404, an OR gate 1405 and an integrated clock gating cell 1406.

In one of the embodiments, the synchronous finish pulse signal sync_finish_pls, the delayed write synchronous signal wrbusy_sync_d and the write synchronous signal wrbusy_sync are input to the OR gate 1401. The output terminal of the OR gate 1401 is coupled to the asynchronous setting terminal Sn of the flip-flop 1403. The write pulse signal wrbusy passes through the inverter 1402 and is coupled to the asynchronous setting terminal Sn of the flip-flop 1403. The receiver clock signal receive_clk is coupled to the clock input terminal of the flip-flop 1403. The output terminal Q of the flip-flop 1403 is coupled to an input terminal of the OR gate 1404. Another input terminal of the OR gate 1404 is coupled to the output terminal of at least one OR gate 1405, and the OR gate 1405 receives a restore enable signal restore_en as the input. The output terminal of the OR gate 1404 is coupled to the input terminal of the ICG cell 1406. Another input terminal of ICG cell 1406 receives a restore clock signal restore_clk, and the output terminal of ICG cell 1406 outputs the gated receiver clock signal receive_clk_g.

The embodiment utilizes the ICG cell 1406 to gate the receiver clock signal receive_clk, and provides the clock signal to the synchronizer only when needed, thereby reducing the dynamic power consumption of the synchronizer. Since the write pulse signal wrbusy and the receiver clock signal receive_clk are asynchronous signals, when the signal wrbusy changes from logic low to logic high, it may cause the ICG cell 1406 to produce a one-cycle metastable. However, with the clever design of the above circuit, the metastability of this cycle does not cause errors to the entire synchronous circuit.

More detailed, when the write pulse signal wrbusy is changed from logic high to logic low, because the setting terminal Sn of the flip-flop 1403 receives the inverting signal of the write pulse signal wrbusy through the inverter 1402, so when the signal wrbusy is changed to logic low, the data input terminal D of the flip-flop 1403 still maintains logic high, so that the output terminal of the ICG cell 1406 will not be metastable. Through this circuit design, the asynchronous relationship between the write pulse signal wrbusy and the receiver clock signal receive_clk can effectively avoid the problem of clock domain crossing.

The receiver clock signal receive_clk is gated through the ICG cell 1406, which can avoid unnecessary clock signal flip during asynchronous operation, and effectively reduce the dynamic power consumption of the synchronizer. In addition, the present invention solves the metastable problem that may arise due to the asynchronous relationship between the write pulse signal wrbusy and the receiver clock signal receive_clk through a special circuit design, and ensures the stability and reliability of the synchronous circuit.

FIG. 13 is a schematic diagram of the clock gating circuit architecture of another embodiment in this disclosure.

In order to further reduce the power consumption of the synchronizer, the invention not only introduces the clock gating mechanism to the receiver clock signal receive_clk, but also proposes a simple and effective clock gating circuit architecture for the transmitter clock signal transmit_clk, as shown in FIG. 13.

In FIG. 13, the clock gating circuit 1500 mainly includes an OR gate 1501 and an ICG cell 1502. An input terminal of the OR gate 1501 receives a write pulse signal wrbusy, and another input terminal receives a delayed write pulse signal wrbusy_d. The output terminal of the OR gate 1501 is coupled to an input terminal of the ICG cell 1502. Another input terminal of ICG cell 1502 receives the transmitter clock signal transmit_clk, and the output terminal of ICG cell 1502 outputs the gated transmitter clock signal transmit_clk_g.

The embodiment utilizes an ICG cell 1502 to the gated transmitter clock signal transmit_clk. When the write pulse signal wrbusy is a logic low, it means that there is no data to be synchronized at present, and the ICG cell 1502 turns off the output terminal of the transmitter clock signal transmit_clk, thereby reducing the dynamic power consumption of the transmitter circuit in the synchronizer. When the write pulse signal wrbusy is transitioned to logic high, it means that data synchronization is required, and the ICG cell 1502 turns on the output of the transmitter clock signal transmit_clk, so that the synchronizer can carry out normal synchronization process.

In more detail, since the input signals (write pulse signal wrbusy and delayed write pulse signal wrbusy_d) of the OR gate 1501 are asynchronous signals, the direct use of the control ICG cell 1502 may cause timing problems. Therefore, the present embodiment carries out logic OR operation on the write pulse signal wrbusy and the delayed write pulse signal wrbusy_d through OR gate 1501, so as to ensure that in the transition process of the write pulse signal wrbusy and the delayed write pulse signal wrbusy_d, the input terminal of the ICG cell 1502 is always maintained as logic high, so as to avoid generating unnecessary flipping of gated transmitter clock signal transmit_clk_g, and achieve a better power-saving mechanism. Wherein, the delayed write pulse signal wrbusy_d is a delay signal generated after the write pulse signal wrbusy passes through one or more delay components (such as a flip-flop or a buffer) to ensure that the input terminal of the ICG cell 1502 can be maintained at a high level near the rising and falling edges of the write pulse signal wrbusy.

Compared with the clock gating circuit with the receiver clock signal receive_clk, the clock gating circuit 1500 of the transmitter clock signal transmit_clk in the present embodiment is more concise, and only one OR gate 1501 and one ICG cell 1502 can be implemented. This simple design not only reduces circuit complexity, but also reduces additional hardware costs and layout area.

In general, the semiconductor device of the present invention has a multi-bit synchronizer circuit architecture and control method with low power consumption and data retention function, which not only solves the problem of data loss of synchronizer after power-off in prior art, but also achieves the following remarkable effects through a series of circuit design optimization and control method innovation: 1. Effectively reduces the power consumption during circuit operation; 2. Improve the efficiency and reliability of data synchronization; 3. Simplifying the complexity of circuit design, thereby reducing the chip area and cost; Fourth, it provides a more flexible and accurate data retention and restore mechanism, which can be adapted to a variety of different power management strategies; 5. Improve the stability and reliability of the system in the process of switching between power-saving modes.

In summary, the present invention has high industrial utilization value, and can be widely used in a variety of high-efficiency, low power consumption and semiconductor devices that require multiple power supply regions and/or multiple clock domains, such as mobile communication devices, Internet of Things (IoT) devices, wearable electronic devices, etc.

Although the present disclosure has been described as above with preferred embodiments, it's not intended to limit the scope of the present disclosure. Any person ordinarily skilled in the art can make some modifications and embellishments without departing from the spirit and scope of the present disclosure. Therefore, the protection scope of the present disclosure shall be subject to the scope defined by the appended claims.

What is claimed is:

1. A semiconductor device, comprising:
a first circuit block, configured to receive power from a first power supply region, and configured to operate according to a first clock signal, wherein the first circuit block comprises a multi-bit synchronizer and a register controller, the register controller comprises at least one first storage element, and the register controller is configured to output a write pulse signal to the multi-bit synchronizer;
a second circuit block, configured to receive power from a second power supply region wherein the second circuit block comprises a clock gating cell and a data retention circuit, the clock gating cell is configured to selectively output a second clock signal according to a gating signal, and the data retention circuit is coupled to the multi-bit synchronizer;
wherein, when the semiconductor device enters a power-saving mode, the first power supply region is powered off, and the second circuit block causes the clock gating cell to output the second clock signal according to a save enable signal;
when the semiconductor device leaves the power-saving mode, the power supply in the first power supply region is restored; and
when the save enable signal is at a second logic level, the second circuit block controls the clock gating cell to stop outputting the second clock signal;
wherein, when power supply is restored to the data retention circuit after the first power supply region is powered off, a state value of an output signal of the first storage element before power-off is provided to the multi-bit synchronizer.

2. The semiconductor device as claimed in claim 1, wherein the clock gating cell is an integrated clock gating cell, and the write pulse signal and a delayed write pulse signal are connected to an input terminal of the integrated clock gating cell through an OR gate.

3. The semiconductor device as claimed in claim 1, wherein the register controller further comprises:
a read/write controller, configured to control data writing and reading of the first storage element, wherein when at least one circuit control parameter is modified by the read/write controller in the first storage element, the write pulse signal output by the read/write controller is transitioned to a first logic level.

4. The semiconductor device as claimed in claim 1, wherein the multi-bit synchronizer comprises:
a plurality of flip-flops connected in series to synchronize the output signal of the first storage element to a clock domain of the second clock signal and generate a synchronous output signal.

5. The semiconductor device as claimed in claim 4, wherein the data retention circuit comprises:
a second storage element; and
a multiplexer;
wherein, before entering the power-saving mode, the second circuit block retains a value of the synchronous output signal after synchronization as the state value through the clock gating cell and the second storage element.

6. The semiconductor device as claimed in claim 1, wherein the multi-bit synchronizer comprises:
a synchronous control circuit block, configured to determine whether the synchronous control circuit block is in a busy state according to the write pulse signal received by the multi-bit synchronizer;
a data retention cell block, configured to write the state value received by the multi-bit synchronizer from the second storage element to an output terminal of the multi-bit synchronizer according to a restore enable signal after power was restored to the first power supply region; and
a state control circuit block, configured to output a clear busy signal.

7. The semiconductor device as claimed in claim 6, wherein the output terminal of the data retention cell block comprises:
a flip-flop, including a setting terminal, wherein the data retention cell block selectively controls the setting terminal according to the restore enable signal, and writes the state value to the output terminal of the flip-flop.

8. The semiconductor device as claimed in claim 1, wherein the first circuit block further comprises:
a scheduler, configured to store a plurality of addresses and data to be written to the first storage element, and to sequentially provide the plurality of addresses and data to the read/write controller.

9. The semiconductor device as claimed in claim 8, wherein when the plurality of addresses and data stored in the scheduler have been written to the first storage element, and a corresponding synchronization operation has been completed, the scheduler outputs a clear status signal.

10. The semiconductor device as claimed in claim 6, wherein the restore enable signal is a multi-bit signal, each bit of the multi-bit signal corresponds to an output bit of the multi-bit synchronizer, and the state control circuit block determines whether to write bit values of a corresponding data retention signal to the output bits of the multi-bit synchronizer according to each bit value of the restore enable signal.

11. The semiconductor device as claimed in claim 1, wherein the semiconductor device determines whether a synchronization operation is completed by polling a status of the write pulse signal.

12. The semiconductor device as claimed in claim 5, wherein the first storage element and the second storage element are configured to share the write pulse signal.

13. The semiconductor device as claimed in claim 6, wherein the data retention cell block comprises:
a first multiplexer including:
a first input terminal;
a second input terminal;
a selection terminal, configured to receive a selection signal; and
an output terminal;
a second multiplexer including:
a first input terminal, configured to receive a first data;
a selection terminal, configured to receive the restore enable signal; and an output terminal;
a third multiplexer including:
a first input terminal, coupled to the output terminal of the first multiplexer;
a second input terminal, coupled to the output terminal of the second multiplexer;
a selection terminal; and
an output terminal; and
a first flip-flop including:
an input terminal, coupled to the output terminal of the third multiplexer; and
an output terminal, configured to output an output signal.

14. The semiconductor device as claimed in claim 6, wherein the data retention cell block comprises:
a first multiplexer including:
a first input terminal;
a second input terminal;
a selection terminal, configured to receive a selection signal; and
an output terminal; and
a first flip-flop including:
a first input terminal, coupled to the output terminal of the first multiplexer;
a second input terminal, configured to receive the restore enable signal;
a third input terminal, configured to receive a data input signal; and
an output terminal, configured to output an output signal.

15. The semiconductor device as claimed in claim 6, wherein the multi-bit synchronizer is configured in the first power supply region, and the data retention cell block comprises a plurality of data retention cells configured in a plurality of power supply regions, respectively;
the restore enable signal is configured to control whether the corresponding bit in an output signal corresponding to the restore enable signal needs a data input signal from any of the plurality of power supply regions to restore to values before power-off.

16. The semiconductor device as claimed in claim 1, further comprising a receiving clock generator, wherein the receiving clock generator comprises:
a first OR gate including:
a first input terminal, configured to receive a synchronous finish pulse signal;
a second input terminal, configured to receive a write synchronous signal synchronously processed from the write pulse signal;
a third input terminal, configured to receive a delayed write synchronous signal delayed processed from the write pulse signal; and
an output terminal;
a first flip-flop including:
a first input terminal, coupled to the output terminal of the first OR gate; and
an output terminal;
a second OR gate including:
a first input terminal, coupled to the output terminal of the first flip-flop;
a second input terminal, configured to receive a restore enable signal; and
an output terminal; and
a first integrated clock gating cell including:
a first input terminal, coupled to the output terminal of the second OR gate;
a second input terminal, configured to receive a receiver clock signal; and
an output terminal, configured to output a gated receiver clock signal.

17. The semiconductor device as claimed in claim 1, further comprising a transmitting clock generator, wherein the transmitting clock generator comprises:
a first OR gate including:
a first input terminal, configured to receive the write pulse signal;
a second input terminal, configured to receive a delayed write pulse signal delayed processed from the write pulse signal; and
an output terminal; and
a first integrated clock gating cell including:
a first input terminal, coupled to the output terminal of the first OR gate;
a second input terminal, configured to receive a transmitter clock signal; and
an output terminal, configured to output a gated transmitter clock signal.
